(19) United States
(12) Patent Application Publication
(10) Pub. No.: US 2005/0286238 A1
(43) Pub. Date: Dec. 29, 2005

(54) Device and method of manufacture of an interconnection structure for printed circuit boards

(76) Inventor: Stephen C. Joy, Seattle, WA (US)

Correspondence Address: SEED INTELLECTUAL PROPERTY LAW GROUP PLLC, 701 FIFTH AVE, SUITE 6300, SEATTLE, WA, 98104-7092, US

(21) Appl. No.: 10/875,964

(22) Filed: Jun. 24, 2004

(51) Int. Cl. H05K 1/18

(52) U.S. Cl. 361/761; 361/763; 174/267

(57) ABSTRACT

An interconnection structure for coupling conductive layers of a circuit board includes a pin configured to be press-fitted in an aperture traversing the circuit board, to electrically couple the conductive traces. The pin may be placed in a predrilled aperture, or driven into the circuit board, forming the aperture thereby. The pin may also be configured as a punch, removing a plug of material as it is driven therethrough. The pin may comprise a capacitive or resistive region configured to capacitively or resistively couple the first and second traces. The pin may be configured such that capacitive or resistive values are selectable according to a depth to which the pin is positioned in the aperture. The pin may serve as an offset post for mounting the circuit board to a chassis. In such a case, the pin may be provided with a longitudinal aperture configured to receive a threaded screw.

### BACKGROUND OF THE INVENTION

1. Field of the Invention

This patent application is directed generally to the field of circuit board manufacture, and in particular to structures for interconnecting conductive layers thereof.

2. Description of the Related Art

Most modern electronic systems employ one or more printed circuit boards (PCB's) of varying degrees of complexity. For example, some simple electronic devices employ circuit boards having a single conductive layer laminated to one of the faces thereof, from which a circuit is etched. Other devices employ circuit boards having conductive layers laminated on opposing faces thereof, each of which is etched with a different circuit pattern. More complex circuit boards, employing internal conductive layers, as well as conductive layers on each outer surface, are well known in the art.

In circuit boards employing more than a single conductive layer, means for interconnecting the various conductive layers must be provided. FIG. 1 illustrates a known structure provided for the purpose of interconnecting varying conductive layers of a circuit board. The structure 100 is commonly referred to as a plated-through-hole (PTH). A nonconductive substrate 102 is provided, having first and second conductive layers 104, 106, formed on the opposing faces thereof. An internal conductive layer 112 is shown formed between nonconductive portions of the substrate. In some very complex systems circuit boards exceeding twenty or thirty conductive layers laminated between nonconductive substrate layers are known in the art. It will be understood that, while only a single internal layer 112 is shown for purposes of illustration and clarity, the circuit board depicted may include many more conductive layers. The PTH 100 includes a barrel portion 108 and upper and lower pad portions 110. Formation of a PTH in a circuit board requires a number of etching and plating steps, and is generally performed prior to etching of the outer conductive layers 104, 106 for forming circuit traces on the surfaces of the substrate 102.

Plated-through-holes are also frequently used for mounting electronic components on the printed circuit board. Leads of the various electronic components are positioned such that each lead passes through a PTH and terminates a short distance beyond the opposite surface of the PCB. When solder is applied to one surface of the board, it passes via capillary action through the plated-through-hole and provides a secure mechanical and electrical coupling for the respective lead. However, many components manufactured according to newer technology do not employ leads configured to pass through a circuit board, but rather employ surface mounting techniques, which do not require plated-through-holes, but are rather affixed to pads formed on a face of a PCB. Thus, the number of plated-through-holes required on a circuit board is reduced. However, the need still remains for an interconnection structure to provide continuity between various conductive layers of a PCB.

### BRIEF SUMMARY OF THE INVENTION

According to an embodiment of the invention, an interconnection structure is provided, for electrically coupling a first conductive trace in a first layer of a circuit board to a second conductive trace in a second layer of the circuit board. The structure includes a pin configured to be positioned in an aperture traversing the circuit board, the pin further configured to electrically couple the first and second conductive traces.

According to an embodiment of the invention, the pin comprises a capacitive region configured to capacitively couple the first and second conductive traces. The capacitive region may be configured to be selectable according to a depth to which the pin is positioned in the aperture. The capacitive region comprises a conductive core region, a dielectric layer surrounding the conductive core region, and a conductive outer layer surrounding the dielectric layer. The conductive core region may also have a convoluted or stellate shape in transverse cross section.

According to another embodiment of the invention, the pin comprises a resistive region configured to resistively couple the first and second conductive traces. A resistive value of the resistive region may be configured to be selectable according to a depth to which the pin is positioned in the aperture.

According to an embodiment of the invention, the pin comprises a plurality of longitudinal ridges configured to interpenetrate a surface of the aperture.

According to an embodiment of the invention, an electronic circuit assembly is provided, including a circuit board having upper and lower surfaces, an aperture formed in the circuit board traversing the circuit board from the upper surface to the lower surface, and a pin positioned in the aperture. The pin includes first and second ends, and the first end may terminate flush with the upper surface of the circuit board and the second end may terminate flush with the lower surface of the circuit board.

According to an additional embodiment, the circuit assembly includes first and second conductive layers formed in the circuit board, and the pin is configured to electrically couple the first and second conductive layers.

According to other embodiments of the invention, methods of manufacture and operation are provided.

Advantages of the invention over previously known art include reduced manufacturing times and costs, reduced environmental impact, increased flexibility in circuit design and adjustment, and improved component inventory control.

### BRIEF DESCRIPTION OF THE SEVERAL VIEWS OF THE DRAWING(S)

In the drawings, identical reference numbers identify similar elements or acts. The sizes and relative positions of elements in the drawings are not necessarily drawn to scale. For example, the shapes of various elements and angles are not drawn to scale, and some of these elements are arbitrarily enlarged and positioned to improve drawing legibility. Further, the particular shapes of the elements as drawn may be selected merely for ease of recognition in the drawings.

FIG. 1 shows a section of a circuit board according to known art, in which a plated-through-hole is formed.

FIG. 2 shows an interconnection pin in a circuit board according to an embodiment of the invention.

FIG. 3 shows the interconnection pin of FIG. 2 at a different stage of the manufacturing process.

FIGS. 4-6 show interconnection pins in circuit boards according to various embodiments of the invention.

FIG. 7 shows the interconnection pin of FIG. 6 in a transverse cross section.

FIG. 8A shows an interconnection pin in a circuit board according to another embodiment of the invention.

FIGS. 8B-8D show the interconnection pin of FIG. 8A according to one alternative embodiment, in which the pin is illustrated at various depths in the circuit board.

FIG. 8E shows the interconnection pin of FIG. 8A according to another alternative embodiment.

FIG. 9 shows the interconnection pin of FIG. 8A in transverse cross section, according to an alternative embodiment.

FIG. 10 shows the interconnection pin of FIG. 8A in transverse cross section, according to another alternative embodiment.

FIGS. 11-17 show interconnection pins in circuit boards according to various embodiments of the invention.

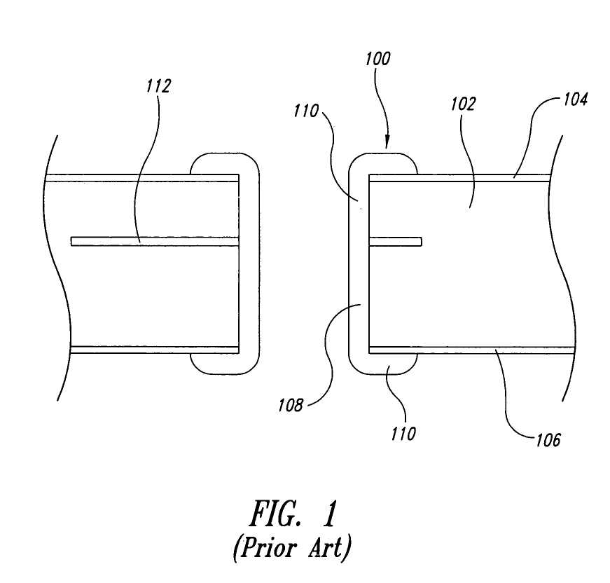

### DETAILED DESCRIPTION OF THE INVENTION

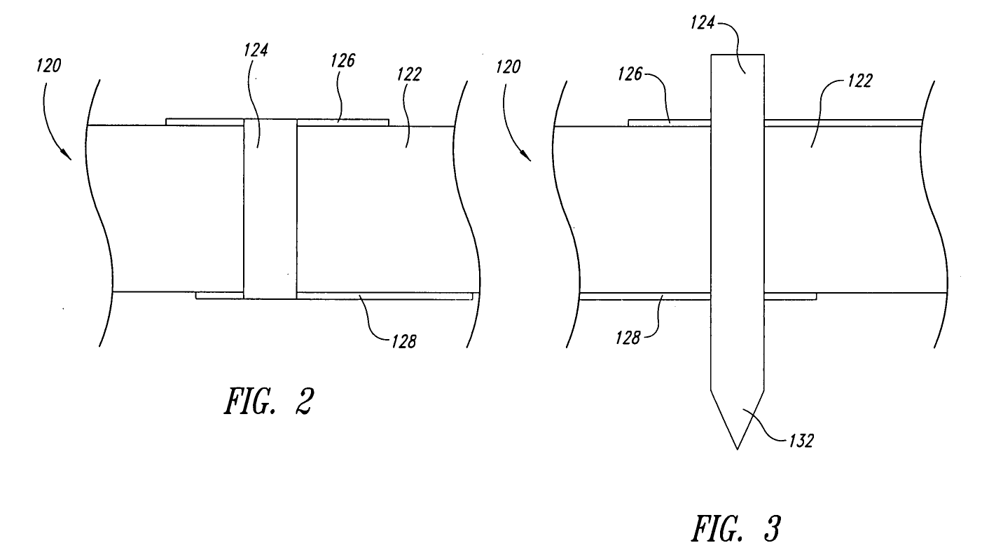

According to an embodiment of the invention, an interconnection structure is provided as illustrated in FIG. 2. A printed circuit board 120 having a substrate 122 is shown having upper and lower conductive layers 126, 128 and an interconnection pin 124 traversing the substrate 122 from one face to the other, and providing an electrically continuous connection between the upper and lower conductive layers 126, 128. According to one embodiment of the invention, the interconnection pin 124 is positioned in the substrate 122 and with the ends thereof flush with the surfaces 127, 129 of the PCB 120. Either or both of the surfaces 127, 129, may comprise outer surfaces of the upper and lower conductive layers 126, 128, respectively, or alternatively, may comprise outer surfaces of the non-conductive substrate 122.

While generally referred to simply as layers in this description, conductive layers 126, 128, as well as other conductive layers referred to herein, may comprise lands, traces, vias, or any other conductive structure formed in or on the substrate, whether by printing, etching, depositing, plating, or any other process. Such features may be referred to as being “in” the circuit board, even when comprising an outer surface thereof.

FIG. 3 shows the pin 124 in press-fit engagement with the substrate 122. Following positioning of the pin 124 in the substrate 122, the ends thereof may be sheared off or ground and polished until flush with the surfaces 127, 129 of the PCB 120, as shown in FIG. 2.

The interconnection pin 124 of FIG. 3 includes a tapered point 132. According to one method, the interconnection pin 124 is driven into the substrate 122 with sufficient force to fully penetrate the substrate 122. When inserting the interconnection pin 124 in this manner it may be advantageous to heat the interconnection pin 124 or the substrate 122 in the immediate region, such that the pin 124 penetrates without excessive damage to the substrate 122.

According to some embodiments of the invention, some minimal substrate damage is tolerable, provided that no electrically conductive layers or traces are compromised.

According to another embodiment of the invention, a hole is predrilled or pre-punched in the substrate 122. The diameter of the hole is selected to permit passage of the interconnection pin 124, while holding the pin securely once inserted.

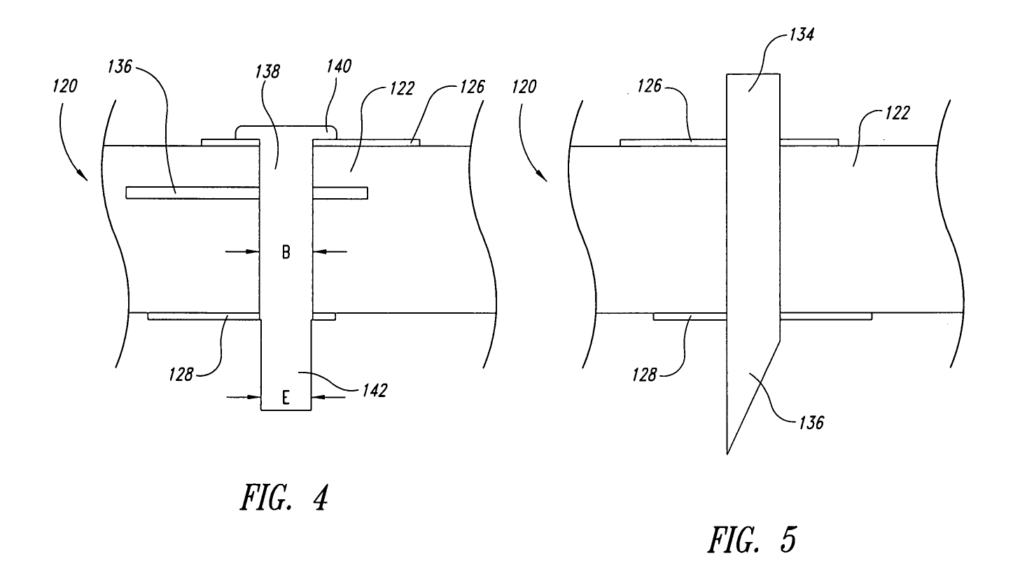

FIG. 4 shows an interconnection pin 138 according to further embodiment of the invention. Interconnection pin 138 includes a squared off end 142 configured to remove a plug of material from the substrate 122 as it is driven through the substrate.

Mechanical punches configured to punch holes in circuit board substrates are known in the art. Such punches generally include a support surface on which a circuit board is positioned and in which punching dies are formed having apertures aligned with a punch such that, as the punch penetrates the circuit board substrate, a plug of material is removed from the substrate by a shearing action as the punch penetrates the substrate and passes into the aperture.

By providing an interconnection pin 138 having an end 142 configured to function in the manner of a punch, a machine may be configured to drive the interconnection pin 138 through the substrate 122 in a position aligned with a cutting die in the manner described with reference to a punching machine. However, instead of withdrawing the punch from the substrate, as would be the case in a known punching system, the interconnection pin 138 is left positioned in the substrate for the purpose of providing electrical interconnection between conductive layers. It is known that, due to memory effect, when a hole is punched in a circuit board substrate, the diameter of the hole tends to reduce slightly immediately after the punch is withdrawn. In the case of the interconnection pin 138, this same memory effect causes the substrate 122 to tightly grip the outer surface of the pin 138 in a firm, press-fit contact.

In the event that a tighter press-fit is desired, the interconnection pin 138 may be manufactured having a first outside diameter E at the leading end 142 transitioning out to a larger diameter B along the barrel of the pin 138. In this way, a tighter union is provided between the interconnection pin 138 and the substrate 122.

The interconnection pin 138 in FIG. 4 is shown having a head 140 on an upper end thereof. The head 140 is configured to provide increased surface area for improved electrical contact between the pin 138 and the conductive layer 126. According to an alternate embodiment, the pin 138 may be provided with a smooth barrel as illustrated with reference to FIG. 3.

The substrate 122 of FIG. 4 is shown having an internal conductive layer 136 through which the pin 138 passes, providing electrical continuity between the inner conductive layer 136 and the upper and lower conductive layers 126, 128. It will be understood that the substrate 122 may include additional internal conductive layers.

According to an embodiment of the invention illustrated in FIG. 5, an interconnection pin 134 is provided having a beveled point 136. The beveled point 136 may provide improved punching characteristics in some types of circuit board substrate material.

FIG. 6 shows an interconnection pin 150 according to another embodiment of the invention. Interconnection pin 150 is provided with a plurality of vertical flutes and ridges 152. The ridges 152 extend longitudinally along at least a portion of the length of the pin 150, and are configured to provide improved electrical continuity between the interconnection pin 150 and the conductive layers 126, 128, 136 of the substrate 122.

Whether the interconnection pin 150 is pressed through the substrate, as described with reference to FIG. 3, punched through the substrate, as described with reference to FIG. 4, or positioned in a predrilled hole, also as previously described, a smooth sided pin may be inadequate to provide firm contact with each of the conductive layers of the substrate, especially those formed internally, such as layers 136 of FIG. 6. Accordingly, the longitudinal ridges 152 of the interconnection pin 150 are configured to cut slightly, or interpenetrate into the substrate 122 and conductive layers 126, 128, 136, providing dependable electrical contact with each conductive layer.

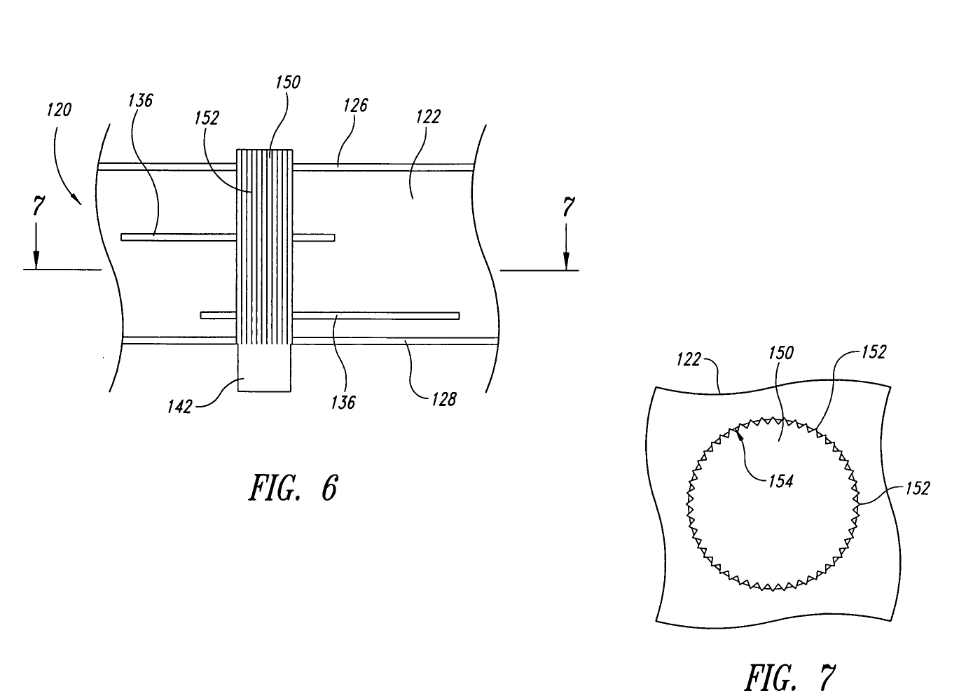

FIG. 7 shows the interconnection structure of FIG. 6 in a sectional view taken along the lines 7-7, with the pin 150 shown in the substrate 122. The ridges 152 may be seen to penetrate slightly into a surface 154 of an aperture provided in the substrate 122. Each ridge 152 makes separate contact with each conductive layer, providing redundant connections therebetween.

According to the embodiment illustrated, the interconnection pin 150 of FIGS. 6 and 7 is provided with an end 142 configured to be used as a punch, as described with reference to the pin 138 of FIG. 4. The punch end 142 of the pin 150 may have an outer diameter that is slightly smaller than the outer diameter of the ridged portion of the interconnection pin 150, thus ensuring a strong mechanical and electrical connection.

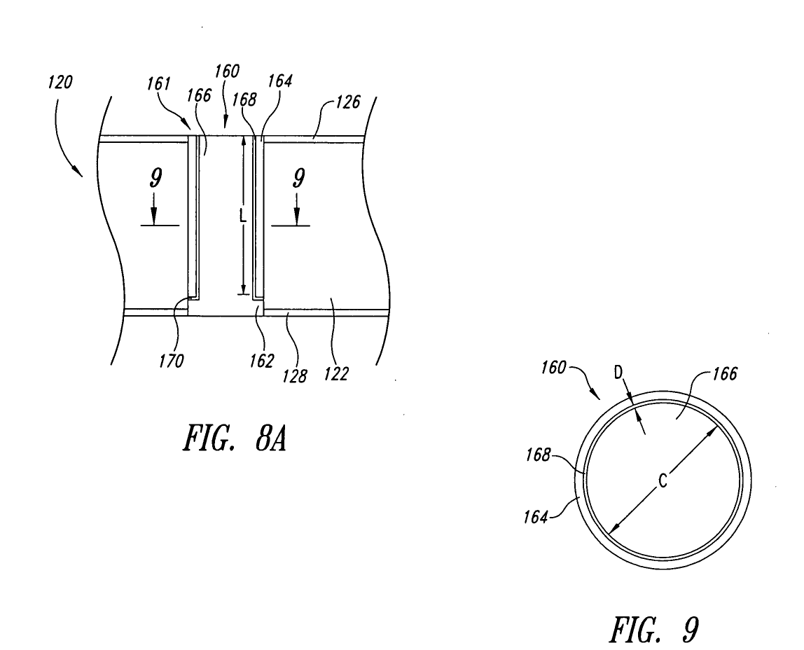

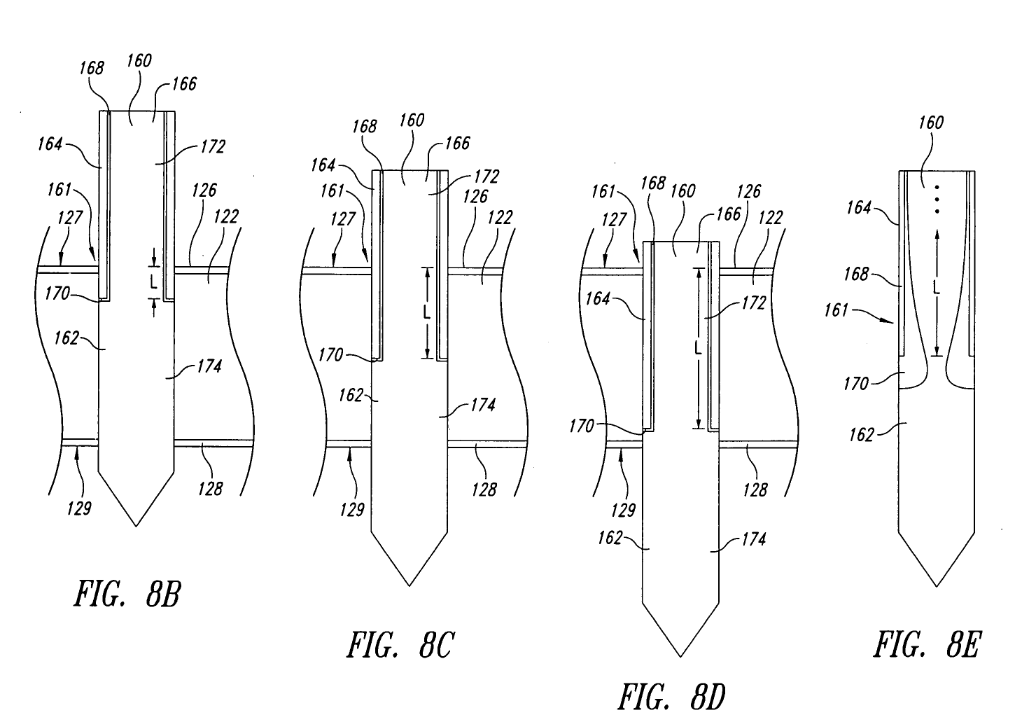

Referring now to FIGS. 8A and 9, an interconnection pin 160 is illustrated, in which a capacitor is incorporated into the structure of the pin 160. The pin 160 comprises a core region 166 formed of a conductive material, a dielectric region 168, and an outer conductive layer 164. The outer conductive layer 164 is separated from the core region 160 by the dielectric layer 168. The core region 160 is in electrical contact with a shoulder region 162, which defines the outside diameter of the interconnection pin 160. The dielectric layer 168 includes a termination region 170.

According to an embodiment of the invention, the core region 166, the dielectric layer 168, and the outer conductive layer 164 are formed coaxially with each other, with an outer diameter of the outer conductive layer being substantially equal to the outer diameter of the shoulder region 162. The termination region 170 serves to electrically separate the shoulder region 162 vertically from the outer connective layer 164.

It will be recognized that, inasmuch as the capacitive value of a capacitor is controlled by factors such as the total surface area of conductors separated by a dielectric, as well as the thickness of the dielectric, the capacitive value of the capacitor incorporated in the interconnection pin 160 is in part controlled by the length L of the outer conductive layer 164. Namely, the longer the dimension L, the greater total surface area of the capacitor, and thus the greater the capacitive value thereof.

Referring now to FIGS. 8B-8D, the interconnection pin 160 is described with reference to an embodiment of the invention. As was described previously with reference to FIGS. 2 and 3, an interconnection pin may be placed in the circuit board substrate 122 and the protruding portions thereof removed and ground or polished flush to upper and lower surfaces 127, 129 of the PCB 120. In the case of the embodiment of FIGS. 8B-8D, the interconnection pin 160 includes a capacitive region 172 and a non-capacitive region 174 divided by the termination region 170. The ultimate value of the capacitor 161 is determined, in part, by the length L of the outer conductive layer 164 that remains after the upper region 172 of the interconnection pin 160 has been machined flush with the upper surface 127 of the PCB 120. By causing the pin 160 to penetrate a selected distance through the substrate 122, the length L can be selected, and accordingly the value of the capacitor 160 can be controlled.

FIGS. 8B-8D each depict the pin 160 after it has been placed in the substrate 122 and prior to removal of the outer portions thereof. FIG. 8B shows the pin having been placed in the substrate at a relatively shallow penetration, resulting in a short dimension L. FIG. 8C shows the pin 160 at a medium penetration, resulting in a longer dimension L, while FIG. 8D shows the pin 160 at a maximum penetration, resulting in a dimension L that is nearly the full width or thickness of the PCB 120.

An advantage of the embodiment described with reference to FIGS. 8B-8D is that a common component may be used in many different applications, with the value of that component being controlled solely by its placement in the substrate 122.

Referring now to FIG. 8E, an alternate embodiment of the interconnection pin 160 incorporating a capacitor 161 is illustrated, in which the thickness of the dielectric layer 168 varies along the length of the pin 160. Accordingly, as the pin 160 is placed more and more deeply into the substrate 122, and as the length L increases, the value of the resulting capacitor 161 rises in a nonlinear fashion.

Referring again to FIG. 9, a cross-section of the interconnection pin 160 is shown as viewed at lines 9-9 of FIG. 8. According to the embodiment of FIG. 9, the core region 166, the dielectric layer 168, and the outer conductive layer 164 are each cylindrical and concentric. As was previously discussed, the capacitive value of the resulting capacitor will depend, in part, on the surface areas of the conductive materials on either side of the dielectric layer 168, and also on the thickness of the dielectric layer 168. Accordingly, these factors are substantially controlled by the diameter C of the core region 166 in combination with the thickness D of the dielectric layer 168.

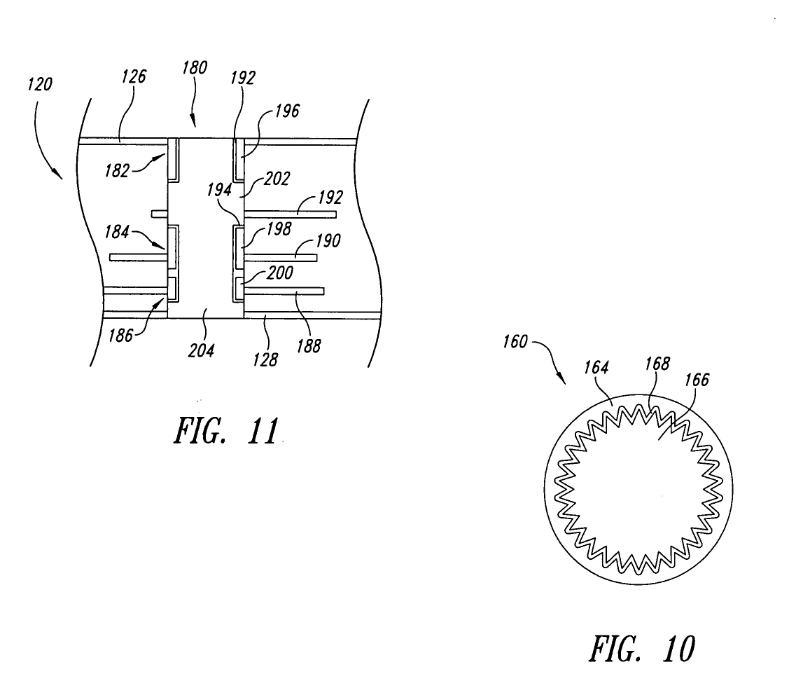

FIG. 10 shows an embodiment of the interconnection pin 160 in which the surface areas of the conductive regions on either side of the dielectric 168 are substantially increased as shown. The core region 160 is formed having a convoluted shape in cross section. The embodiment pictured has a deep stellate pattern with the dielectric layer 168 being formed thereover in a regular thickness. The outer conductive layer 164 is formed to fill the ridges and valleys of the stellate pattern. It may be seen that the facing areas of the core region 166 and the outer conductive layer 164 have significantly greater surface area than the corresponding features of FIG. 9. Accordingly, by controlling the number and depth of ridges in the stellate pattern, and the thickness of the dielectric layer 168, the capacitive value of the resulting capacitor may be influenced.

Other patterns may also be selected to provide a selected area and thus a selected capacitive value.

FIG. 10 shows the interconnection pin 160 as having a smooth cylindrical outer surface. It will be recognized that the outer surface of the interconnection pin 160 may also be formed in the manner described with reference to interconnection pin 152 of FIGS. 6 and 7.

FIG. 11 illustrates an interconnection pin 180 according to another embodiment of the invention. The interconnection pin 180 incorporates capacitors 182, 184, 186 configured to capacitively couple outer conductive layer 128 with the outer conductive layer 126 and inner conductive layers 188, 190. Additionally, inner conductive layer 192 is directly coupled to outer conductive layer 128 via shoulder region 202.

Capacitor 182 is formed by core region 204 surrounded by dielectric layer 192 and outer conductive layer 196, which is in electrical contact with outer conductive layer 126. Capacitor 184 is formed by core region 204, surrounded by dielectric layer 194 and outer conductive layer 198, which is in electrical contact with inner conductive layer 190. Meanwhile, capacitor 186 comprises core region 204, dielectric layer 194, and outer conductive layer 200, which is in electrical contact with inner conductive layer 188.

It may be seen, referring to FIG. 11, that interconnection pins may be configured to incorporate a wide variety of capacitors and conductors. Values of the capacitors may be controlled by selection of lengths of outer conductive layers, as well as other features, such as those described with reference to FIGS. 9 and 10.

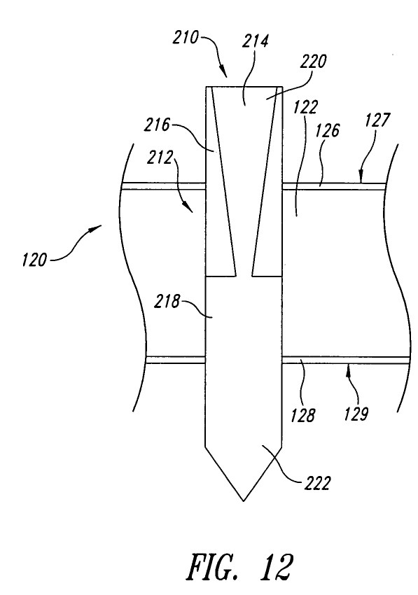

FIG. 12 illustrates an interconnection pin 210 that incorporates a resistor 212. Interconnection pin 210 includes a highly conductive core region 214 and an outer region 216 having a selected resistive value. The interconnection pin 210 is positioned within the substrate 122 at a selected depth, after which the upper and lower regions 220, 222 are removed flush with the upper and lower surfaces 127, 129 of the PCB 120. The resistor 212 provides a resistive coupling between upper and lower conductive layers 126, 128. The lower conductive layer 128 is in electrical contact with the core region 214, while the upper conductive layer 126 is in electrical contact with the resistive region 216. The value of the resulting resistor 212 is determined by factors such as the total surface area between the core region 214 and the resistive region 216, the shortest distance between the outer conductive layer 126 and the core region 214, and the resistive value of the resistive region 216. Such factors are well within the abilities of one of ordinary skill in the art to select. It may be seen that, with respect to the resistor 212 of the embodiment of FIG. 12, the resistive value of the resistor 212 is controlled by the depth to which the interconnection pin 210 is placed in the substrate 122.

According to one embodiment (not shown) of the invention, an interconnection pin is provided having a consistent resistive value such that variations in depth of placement of the pin do not have a substantial effect on the resistive value thereof.

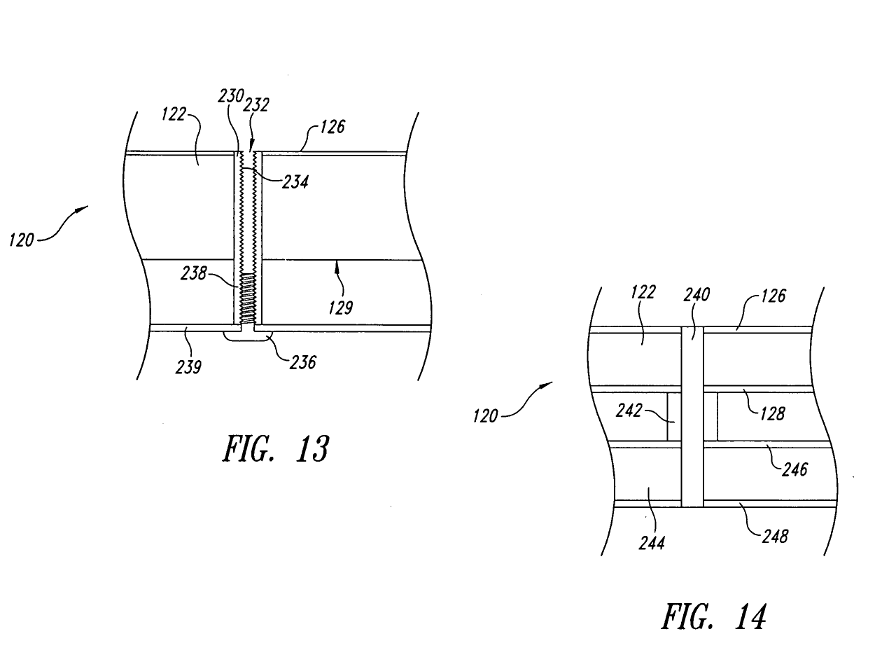

According to another embodiment of the invention, an interconnection pin 230 is provided, as illustrated In FIG. 13. An aperture 232 is positioned axially within the pin 230 and may include internal threads 234. The pin 230 may be positioned in the PCB 120 as previously described, with a lower region 238 extending a selected distance beyond the lower surface 129 of the PCB 120. The pin 230 serves as an offsetting anchor for the substrate 122 to anchor the PCB 120 to a chassis 239 via an anchoring screw 236. The PCB 120 of FIG. 13 includes an upper conductive layer 126 that is in electrical contact with the interconnection pin 230, which provides a system ground to the chassis 239.

According to an alternate embodiment, the outer conduction layer 126 is not present at the location of the pin 230, which thus provides an electrically insulated offset mounting post for the PCB 120.

FIG. 14 illustrates an embodiment in which an interconnection pin 240 is coupled to a first PCB 120 and a second PCB 244, separated by a spacer 242. In this configuration, two substrates are permanently coupled together. Conductive regions 126, 128, 246, 244 may be present at the location of the pin 240 to provide electrical interconnections therebetween.

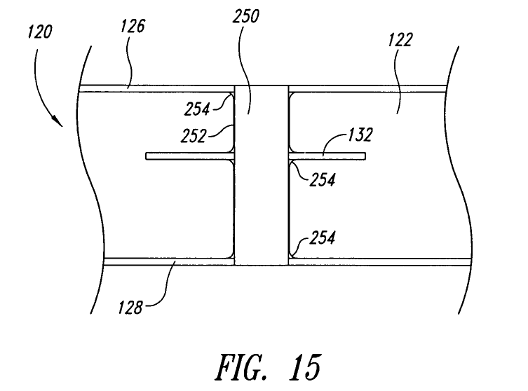

According to an embodiment shown in FIG. 15, an interconnection pin 250 comprises an outer surface 252 including an alloy suitable for creating a solder connection with contacting conductive layers 126, 128, 136 such that, when the pin 250 is heated after positioning in the substrate 122, a solder joint 254 is effected between the pin 250 and each conductive layer. In other embodiments, the outer surface 252 may comprise a conductive polymer or epoxy, which, upon baking of the PCB 120, or other manner of curing, forms a conductive bond between the pin 250 and each conductive layer.

Interconnection pins of various embodiments may also be coupled to conductive layers through the use of ultrasonic welding, cold welding, or other suitable methods.

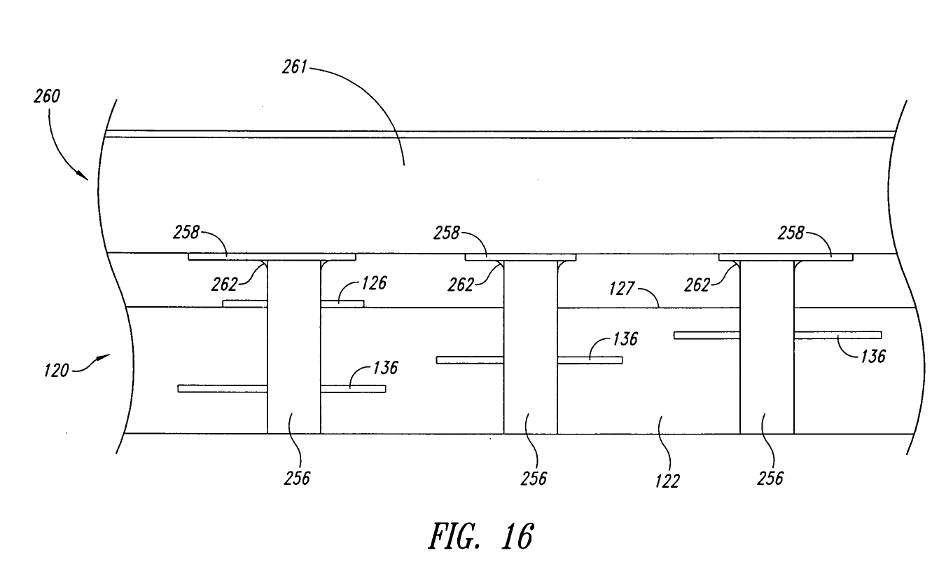

According to an embodiment, the connection pin may be employed for surface mounting one circuit board to another circuit board. For example, as shown in FIG. 16, a plurality of interconnection pins 256 is positioned in a first circuit board 120 to extend a selected distance from a face 127 thereof. A second circuit board 260 having a substrate 261 and contact pads 258 in positions corresponding to the positions of the plurality of pins 256 is positioned over the first circuit board 120. solder connections 262 are then made between each of the pins 256 and a corresponding contact pad 258.

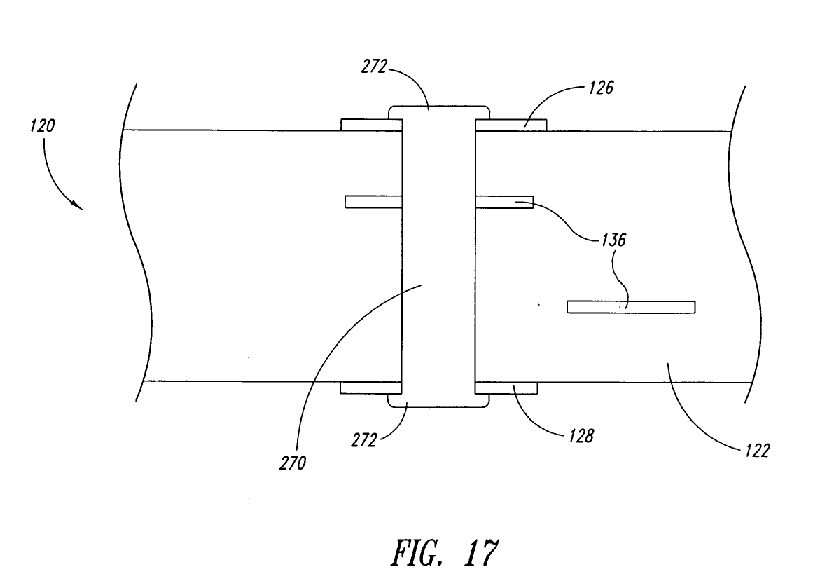

According to the embodiment of FIG. 17, an interconnection pin 270 is provided for interconnecting conductive layers 128, 128, 136. Interconnection pin 270 includes ends 272, which are peened over, thereby providing a robust connection, resistant to discontinuity due to flexures of the circuit board 120.

The various embodiments of the invention provide reduced manufacturing costs, inasmuch as interconnections between various layers of a substrate can be provided using fewer and less costly steps than previously known, and because, in cases where plated-through-holes are completely eliminated, materials used to form the circuit board substrate may be selected from among less expensive formulations. Environmental impact is also reduced with the elimination of the plating steps of PTH formation.

Additionally, fewer components need be maintained in stock, inasmuch as resistive and capacitive values of interconnecting pins may be selected simply by varying the depths thereof. Furthermore, the working costs may be reduced in complex circuit boards, inasmuch as capacitive decoupling values between layers may be modified without reconfiguring conductive layers, as is the case in known art. Interconnection pins may be inserted at various points in the manufacturing process, in contrast to other known interconnection methods, which in general must be performed prior to formation of circuit vias.

In the foregoing description, certain specific details have been set forth in order to provide a thorough understanding of various embodiments of the invention. However, one skilled in the art will understand that the invention may be practiced without these details. In other instances, well-known structures associated with circuit boards, electronic components, and the like have not been shown or described in detail to avoid unnecessarily obscuring descriptions of the embodiments of the invention.

Terms such as “circuit board,” “printed circuit board,” and “PCB” are used in the disclosure and claims to describe this invention. These have been used as terms of convenience, and are not intended to limit the scope of the invention to substrates of a particular type or formulation. Such terms are intended to encompass rigid and flexible substrates of any formulation, and in any appropriate application, including circuit boards, connectors, interconnectors, and ribbon circuits. The principles of the invention may also be employed with advantage in circuits formed on materials not commonly used in electronic circuitry.

An individual having ordinary skill in the art will further recognize many useful variations and combinations not explicitly disclosed in the embodiments illustrated herein. For example, features described with reference to one embodiment may be combined with those of another embodiment to achieve a selected device. Further, the composition and diameter of the interconnection pin may be selected to fulfill requirements of a particular application. Such variations and combinations may be made without deviating from the spirit and scope of the invention. Accordingly, the invention is not limited except as by the appended claims.

1. An electronic circuit assembly, comprising:
a circuit board having upper and lower surfaces;
first and second conductive layers formed in the circuit board;
an aperture formed in the circuit board traversing the circuit board from the upper surface to the lower surface; and
an interconnection pin positioned in the aperture and making electrical contact with the first and second conductive layers, the pin having an outer dimension such as to firmly engage an inner wall of the aperture.

2. The electronic circuit assembly of claim 1 wherein the interconnection pin includes first and second ends, and wherein the first end terminates flush with the upper surface of the circuit board and the second end terminates flush with the lower surface of the circuit board.

3. The electronic circuit assembly of claim 1 wherein at least one of the first and second conductive layers is an inner layer of the circuit board.

4. The electronic circuit assembly of claim 1 wherein the interconnection pin comprises a capacitor, and wherein the first and second layers are capacitively coupled thereby.

5. The electronic circuit assembly of claim 4 wherein the interconnection pin comprises a conductive core region, a dielectric layer surrounding the conductive core region, and a conductive outer layer surrounding the dielectric layer.

6. The electronic circuit assembly of claim 1 wherein the interconnection pin comprises a resistor, and wherein the first and second layers are resistively coupled thereby.

7. The electronic circuit assembly of claim 1 wherein the interconnection pin comprises a plurality of longitudinal ridges on an outer surface thereof, the ridges interpenetrating the inner wall of the aperture.

8. The electronic circuit assembly of claim 1, further comprising:
a solder connection between the interconnection pin and each of the first and second conductive layers.

9. The electronic circuit assembly of claim 1 wherein the circuit board is substantially rigid.

10. The electronic circuit assembly of claim 1 wherein the circuit board is substantially flexible.

11. An interconnection structure for electrically coupling a first conductive trace in a first layer of a circuit board to a second conductive trace in a second layer of the circuit board, comprising:
an interconnection pin configured to be positioned in an aperture having a selected diameter and traversing the circuit board, the pin having an outer diameter selected to firmly engage an inner wall of the aperture, the pin further configured to make electrical contact with the first and second conductive traces.

12. The interconnection structure of claim 11 wherein the interconnection pin comprises a capacitor configured to capacitively couple the first and second conductive traces.

13. The interconnection structure of claim 12 wherein a capacitive value of the capacitor is configured to be selectable according to a depth to which the pin is positioned in the aperture.

14. The interconnection structure of claim 13 wherein the interconnection pin comprises a capacitive region having a conductive core region, a dielectric layer surrounding the conductive core region, and a conductive outer layer surrounding the dielectric layer.

15. The interconnection structure of claim 14 wherein the conductive core region has a convoluted shape in transverse cross section.

16. The interconnection structure of claim 11 wherein the interconnection pin comprises a resistor configured to resistively couple the first and second conductive traces.

17. The interconnection structure of claim 16 wherein a resistive value of the resistor is configured to be selectable according to a depth to which the interconnection pin is positioned in the aperture.

18. The interconnection structure of claim 11 wherein the interconnection pin comprises a plurality of longitudinal ridges configured to interpenetrate a surface of the aperture.

19. The interconnection structure of claim 11 wherein the interconnection pin comprises an aperture formed longitudinally therein, configured to receive a threaded member.

20. The interconnection structure of claim 19 wherein the aperture passes longitudinally from a first end of the interconnection pin to a second end thereof.

21. The interconnection structure of claim 19 wherein the aperture is internally threaded.

22. The interconnection structure of claim 11 wherein the interconnection pin comprises a first end configured to be forcefully driven through the circuit board, thereby forming the aperture.

23. The interconnection structure of claim 22 wherein the interconnection pin is configured to remove a plug of material from the circuit board as it is driven therethrough.

24. An electronic circuit, comprising:
a circuit board having first and second conductive layers; and
interconnecting means for electrically interconnecting the first and second conductive layers.

25. The electronic circuit of claim 24 wherein the interconnecting means comprises a pin traversing the circuit board via an aperture in the circuit board into which it is press-fit.

26. The electronic circuit of claim 25 wherein the pin includes a first end having a tapered point.

27. The electronic circuit of claim 25 wherein the pin includes a first end having a beveled point.

28. The electronic circuit of claim 25 wherein the pin includes a first end configured to function as a punch when driven through the circuit board.

29. The electronic circuit of claim 25 wherein the pin has selected resistive properties.

30. The electronic circuit of claim 25 wherein the pin has selected capacitive properties.

31. The electronic circuit of claim 25 wherein the pin includes longitudinal ridges configured to penetrate a selected distance into a surface of the aperture.

32. The electronic circuit of claim 25 wherein the circuit board comprises a first face, and wherein the pin extends a selected distance beyond the first face of the circuit board.

33. The electronic circuit of claim 24 wherein the circuit board comprises a third conductive layer, and wherein the interconnection means comprises means for electrically interconnecting the third conductive layer with at least one of the first and second conductive layers.

34. A method, comprising:
forming a first conductive layer on a circuit board;
forming a second conductive layer on the circuit board;
forming an aperture through the circuit board, the aperture being positioned to intersect the first and second conductive layers; and
press-fitting an interconnection pin in the aperture in electrical contact with the first and second conductive layers.

35. The method of claim 34, comprising:
removing first and second ends of the pin such that a remaining portion thereof terminates flush with upper and lower surfaces of the circuit board.

36. The method of claim 34 wherein the forming an aperture step comprises driving the pin through the circuit board.

37. The method of claim 36 wherein the driving the pin step comprises removing a plug of material from the circuit board.

38. The method of claim 34 wherein the press-fitting an interconnection pin step comprises selecting a depth of position of the pin.

39. A method, comprising:
applying a first potential to a first conductive trace in a first layer of a circuit board;
applying a second potential to a second conductive trace in a second layer of a circuit board; and
passing current from the first trace to the second trace via an interconnection pin press-fitted into an aperture traversing the circuit board, the pin making electrical contact with the first and second traces.
